(19) United States
(12) Patent Application Publication
(10) Pub. No.: US 2017/0075211 A1
(43) Pub. Date: Mar. 16, 2017

(54) MASK BLANK

(71) Applicant: Asahi Glass Company, Limited, Chiyoda-ku (JP)

(72) Inventor: Kazuyuki HAYASHI, Chiyoda-ku (JP)

(73) Assignee: Asahi Glass Company, Limited, Chiyoda-ku (JP)

(21) Appl. No.: 15/230,775

(22) Filed: Aug. 8, 2016

(30) Foreign Application Priority Data
Sep. 11, 2015 (JP) 2015-179033

(51) Int. Cl. G03F 1/46; H01L 21/033

(52) U.S. Cl. CPC G03F 1/46; H01L 21/0332; H01L 21/0335; H01L 21/0337; H01L 21/0338

(57) ABSTRACT

A mask blank, whereby the deterioration of pattern transfer can be effectively suppressed, when used as a mask for a transferring process.

A mask blank having a transparent substrate, wherein the transparent substrate has a first main surface and a second main surface which are opposed each other, the first main surface is provided with a light-shielding film, the second main surface is provided with an antireflection film, the antireflection film has a first layer and a second layer from the side which is close to the transparent substrate, the reflectivity R₁ to be obtained by removing the antireflection film from the mask blank and irradiating the second main surface side of the transparent substrate with light having a wavelength of 193 nm at an incident angle of 5°, is at least 50%, the ratio R_{A}/R_{S} is at most 0.1, where R_{A} is a reflectivity to be obtained by removing the light-shielding film from the mask blank and irradiating the first main surface side of the transparent substrate with the light at incident angle of 5°, and R_{S} is a reflectivity similarly measured with only the transparent substrate.

### FIELD OF INVENTION

The present invention relates to a mask blank.

### BACKGROUND OF INVENTION

In the semiconductor industry, as a technique to transfer a pattern to form an integrated circuit with a fine pattern on a processed substrate such as a Si wafer, a photolithography method employing visible light or ultraviolet light has been used.

In this method, a transparent substrate (mask) having a light-shielding film on one surface (first main surface) is used. That is, a processed substrate such as a wafer is irradiated with light through a mask to transfer a pattern of a light-shielding film on a surface (usually, a resist surface) of the processed substrate (hereinafter, this process is referred to also as “transferring process”). Then, the resist is subjected to developing treatment to obtain a processed substrate which is provided with the resist having the desired pattern.

Further, recently, along with miniaturization of patterns to be transferred, light to be used becomes short wavelength such as KrF excimer laser (wavelength: 248 nm) or ArF excimer laser (wavelength: 193 nm), and at present, ArF excimer laser is mainly used.

Patent Documents 1 and 2 disclose a photomask and a mask blank for such ArF excimer laser. Further, Patent Document 3 discloses a photolithography reticle, whereby thermal distortion can be reduced.

### PRIOR ART DOCUMENTS

### Patent Documents

Patent Document 1: JP-A-2000-321753

Patent Document 2: WO2008/139904

Patent Document 3: JP-A-2001-166453

### SUMMARY OF INVENTION

### Technical Problem

In conventional masks, a light-shielding film is designed so as to have a light transmittance of about 0.1%. Thus, in the transferring process, most of light which enters into the light-shielding film is absorbed by the light-shielding film and converted to heat. In such a case, a problem may result such that the light-shielding film thermally expands due to the heat, and a mask is distorted. Such thermal expansion of the light-shielding film and distortion of the mask may result in the deterioration of the dimensional accuracy of a pattern to be transferred on a processed substrate. Particularly, light used in the transferring process in recent years has a high energy density, and thereby such a problem may be further significant in future.

And, it is difficult to cope with such a problem, by the construction of the mask described in Patent Document 2.

On the other hand, along with miniaturization of patterns to be transferred, NA is becoming high in the optical system in order to improve the imaging performance and reduce the aberration. If NA becomes high in the optical system, the angle of light to enter into the mask becomes large, and the amount of light to be reflected toward a processed substrate from the mask increases. That is, if light entering from the second main surface (a surface opposite to the first main surface provided with a light-shielding film) of the mask is reflected on the light-shielding film, the reflected light is reflected again on the second main surface, and the light exits from a region of the first main surface where the light-shielding film is absent. If such light reaches a processed substrate, the accuracy of pattern transfer deteriorates.

And, it is difficult to cope with such a problem by the construction of the mask described in Patent Document 1.

Further, it is described in Patent Document 3 that in the reticle, a layer for reflection is formed on the front side of a transparent substrate, and an antireflection coating is formed on the back side of the transparent substrate. However, a specific constitution of such a reticle is not described. Particularly, in order to obtain a reticle having the desired optical properties, it is necessary to sufficiently study properties (such as material composition and film constitution) of the layer for reflection and the antireflection coating depending on light used for the transferring process. Accordingly, it is difficult to cope with the above-mentioned problem by the reticle as described in Patent Document 3.

Therefore, a mask whereby the deterioration of the accuracy of the pattern transfer can be suppressed, is still demanded at present.

The present invention has been accomplished in order to solve the above problem, and it is an object of the present invention to provide a mask blank, whereby the deterioration of the accuracy of the pattern transfer can be sufficiently suppressed, when used as a mask in the transferring process.

### Solution to Problem

The present invention provide a mask blank having a transparent substrate, wherein the transparent substrate has a first main surface and a second main surface which are opposed each other, the first main surface is provided with a light-shielding film, the second main surface is provided with an antireflection film, the antireflection film has a first layer and a second layer from the side which is close to the transparent substrate,

the reflectivity R₁ to be obtained by removing the antireflection film from the mask blank and irradiating the second main surface side of the transparent substrate with light having a wavelength of 193 nm at an incident angle of 81=5°, is at least 50%,

the ratio R_{A}/R_{S} is at most 0.1, where R_{A} is a reflectivity to be obtained by removing the light-shielding film from the mask blank and irradiating the first main surface side of the transparent substrate with the light at incident angle of θ₂=5°, and R_{S} is a reflectivity similarly measured with only the transparent substrate, the antireflection film has a film thickness within a range of from 48 nm to 62 nm, and the first layer of the antireflection film comprises an oxide or oxynitride containing at least one metal selected from aluminum (Al), yttrium (Y) and hafnium (Hf).

### Advantageous Effects of Invention

By the present invention, a mask blank, whereby the deterioration of the accuracy of the pattern transfer can be sufficiently suppressed when used as a mask for the transferring process, can be provided.

### BRIEF DESCRIPTION OF DRAWINGS

FIG. 1 is a view schematically illustrating a conventional mask and how to use it.

FIG. 2 is a schematic cross-sectional view illustrating one embodiment of the mask blank of the present invention.

FIG. 3 is a schematic cross-sectional view illustrating one embodiment of another mask blank of the present invention.

FIG. 4 is a schematic cross-sectional view illustrating one embodiment of further another mask blank of the present invention.

FIG. 5 is a graph showing a mapped area where the ratio R_{A}/R_{S} is at most 0.1 in Ex. 16.

FIG. 6 is a graph showing a mapped area where the ratio R_{A}/R_{S} is at most 0.1 in Ex. 17.

FIG. 7 is a graph showing a mapped area where the ratio R_{A}/R_{S} is at most 0.1 in Ex. 18.

### DESCRIPTION OF EMBODIMENT

Now, embodiments of the present invention will be described with reference to the drawings.

### (Conventional Mask)

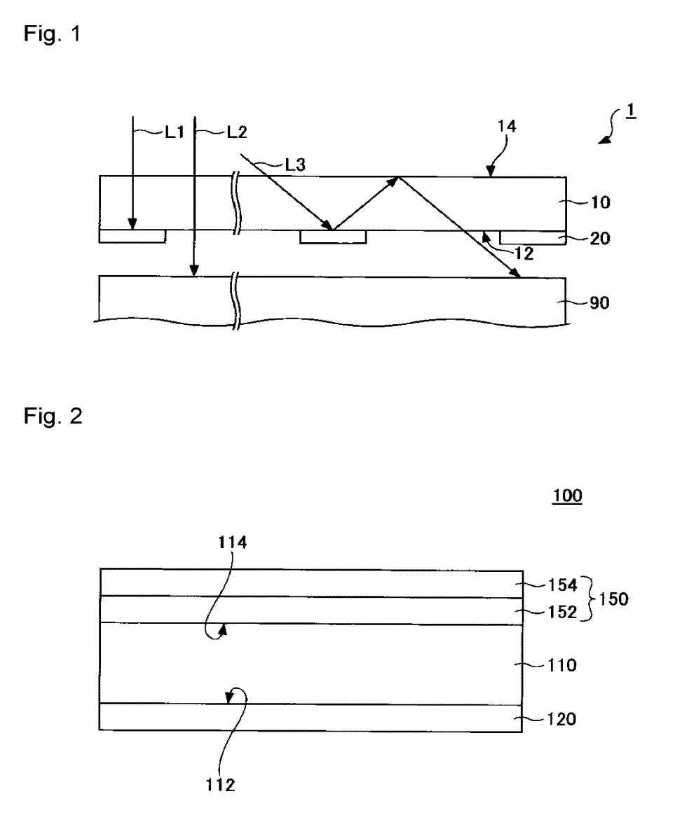

First, in order to better understand the construction and the feature of the present invention, the construction of a conventional mask and its problem will be described with reference to FIG. 1.

FIG. 1 schematically shows the construction of a conventional mask and how to use it.

As illustrated in FIG. 1, the mask 1 has a glass substrate 10 and a light-shielding film 20. The glass substrate 10 has a first main surface 12 and a second main surface 14, and a light-shielding film 20 is formed on the first main surface 12 of the glass substrate 10. The light-shielding film 20 has a predetermined pattern and has a role to block light which enters into the mask 1 from the second main surface 14 of the glass substrate 10.

Such a mask 1 is used in the above-described “transferring process” and for example, can be used for producing an element such as a semiconductor device on a processed substrate by using photolithography.

The transferring process will be more specifically described. First, as illustrated in FIG. 1, a mask 1 is placed above a processed substrate 90 such as a wafer. The mask 1 is placed above the processed substrate 90 so that a side of the light-shielding film 20 would face to the processed substrate 90. A surface of the processed substrate 90 is preliminarily provided with a photosensitive material (not illustrated) such as a resist.

Then, light for transferring a pattern is irradiated from the front side (side of the second main surface 14 of the glass substrate 10) of the mask 1.

The processed substrate 90 is irradiated with light which passes through the mask 1 from a region where the light-shielding film 20 is absent, since the mask 1 has a pattern of the light-shielding film 20. For example, as illustrated in FIG. 1, light L1 irradiated almost vertically to the light-shielding film 20 is blocked by the light-shielding film 20 and does not reach the processed substrate 90, while light L2 irradiated to a region where the light-shielding film 20 is absent passes through the mask 1 and reaches the processed substrate 90. As a result, a photosensitive material of the processed substrate 90 can be subjected to exposure treatment with a desired pattern, whereby the desired pattern can be formed on the photosensitive material on the processed substrate 90.

On the other hand, as described above, most of light L1 irradiated on the light-shielding film 20 is absorbed by the light-shielding film 20 and converted to heat. Further, if the light-shielding film 20 thermally expands due to the heat, and the glass substrate is distorted, a problem may result such that the dimensional accuracy of a pattern to be transferred on the processed substrate 90 deteriorates.

Further, in order to cope with such a problem, it is considered to impart a reflective property to the light-shielding film 20. In such a case, the absorption of light L1 of the light-shielding film 20 is reduced. However, in such a case, as illustrated in the right side of FIG. 1, if light L3 is irradiated at an angle inclined to the light-shielding film 20, the light L3 is reflected by the light-shielding film 20. Such reflected light is reflected again by the second main surface 14 of the glass substrate 10, and then exits from a region where the light-shielding film 20 is absent on the first main surface 12 of the glass substrate 10. If such light reaches the processed substrate 90, not intended regions of the processed substrate 90 are exposed, and the accuracy of pattern transfer deteriorates.

As described above, in a case where the conventional mask 1 is used, there is a problem that it is difficult to transfer a pattern on the processed substrate 90 at a high accuracy.

On the other hand, in a case where the mask blank of one embodiment of the present invention is used as a mask, such a problem can be reduced or solved as described in detail below.

### First Embodiment

Next, one embodiment of the present invention will be described with reference to FIG. 2.

FIG. 2 shows a schematic cross-sectional view of the mask blank of one embodiment of the present invention. In the present specification, the term “mask blank” means a transparent substrate having a light-shielding film to which a desired pattern will be transferred, as is different from a mask having a patterned light-shielding film as shown in FIG. 1. Accordingly, at a stage of “mask blank”, a light-shielding film being a continuous film is placed on a transparent substrate.

In other words, in the “mask blank”, by processing a light-shielding film on a transparent substrate to a desired pattern, a mask for the transferring process is provided.

As illustrated in FIG. 2, the mask blank (hereinafter, referred to as “first mask blank”) 100 of one embodiment of the present invention has a transparent substrate 110, a light-shielding film 120 and an antireflective film 150.

The transparent substrate 110 has a first main surface 112 and a second main surface 114 which are opposed each other, the light-shielding film 120 is formed on the first main surface 112 side of the transparent substrate 110, and the antireflection film 150 is formed on the second main surface 114 side of the transparent substrate 110.

For example, the transparent substrate 110 is made of a transparent material such as quartz glass.

The light-shielding film 120 has a role to prevent light irradiated from the side of the second main surface 114 of the transparent substrate 110 from leaking to the outside of the first mask blank 100 through the first main surface 112 of the transparent substrate 110.

The antireflection film 150 is composed of plural layers. For example, in an example illustrated in FIG. 2, the antireflection film 150 is composed of two layers of a first layer 152 and a second layer 154. The first layer 152 is formed at the side close to the transparent substrate 110 as compared with the second layer 154.

The antireflection film 150 has a role to help light irradiated from the inside of the transparent substrate 110 to the second main surface 114 of the transparent substrate 110 to come out of the first mask blank 100. In other words, the antireflection film 150 has a role to suppress light irradiated from the inside of the transparent substrate 110 to the second main surface 114 of the transparent substrate 110 from being reflected there and coming out of the first mask blank 100 through the first main surface 112.

When the first mask blank 100 having such a construction is used, the light-shielding film 120 is processed to have a desired pattern, and the first mask blank 100 is used as a mask for the transferring process (hereinafter referred to as “first mask”). In such a case, the first mask is placed above a processed substrate such as a wafer so that the side of the light-shielding film 120 would face to the processed substrate. A surface of the processed substrate is preliminarily provided with a photosensitive material such as a resist. Then, from the side of the antireflection film 150 of the first mask, light for pattern transfer, for example, ArF excimer laser having a wavelength of 193 nm is irradiated.

The first mask has the pattern of the light-shielding film 120, whereby light is blocked at a region where the light-shielding film 120 is present. That is, light passes through the first mask from a region where the light-shielding film 120 is absent, and the light is irradiated on the processed substrate. Thus, a desired pattern can be transferred to a photosensitive material on the processed substrate.

Here, the first mask blank 100 has a feature (first feature) that in a sample (referred to as “first sample”) obtained by removing the antireflection film 150 from the first mask blank 100, the reflectivity R₁ to be obtained by irradiating the second main surface 114 side of the transparent substrate 110 with light (for example, ArF excimer laser) having a wavelength of 193 nm at an incident angle of θ₁=5°, is at least 50%.

Here, the incident angle θ₁ is represented by an inclined angle to the normal line of the second main surface 114 of the transparent substrate 110.

Further, the first mask blank 100 has a feature (second feature) that in a sample (referred to as “second sample”) obtained by removing the light-shielding film 120 from the first mask blank 100, the ratio R_{A}/R_{S} is at most 0.1, where R_{A} is a reflectivity to be obtained by irradiating the first main surface 112 side of the transparent substrate 110 with the light (for example, ArF excimer laser) at an incident angle of θ₂=5°, and R_{S} is a reflectivity similarly measured with only the transparent substrate 110.

Here, the incident angle θ₂ is represented by an inclined angle to the normal line of the first main surface 112 of the transparent substrate 110.

In the case of the first mask blank 100 having such features, by the first feature, when the light-shielding film 120 is irradiated with light, more light can be reflected as compared with conventional mask blanks. Therefore, in the case of the first mask blank 100, heat generation due to light absorption tends not to occur in the light-shielding film 120, and the thermal expansion of the light-shielding film 120 and the distortion of the transparent substrate 110 can be effectively suppressed.

Further, the first mask blank 100 has the second feature. That is, the first mask blank 100 has the antireflection film 150, whereby the reflection of light on the second main surface 114 of the transparent substrate 110 can be effectively suppressed. Thus, in the first mask blank 100, it is possible to effectively suppress such a problem that light reflected on the light-shielding film 120 is reflected again on the second main surface 114 of the transparent substrate 110, and the light through the first main surface 112 is irradiated on a processed substrate.

Accordingly, when the first mask blank 100 is used as a first mask for the transferring process, the deterioration of the accuracy of pattern transfer can be effectively suppressed.

### (Constituting Members of First Mask Blank 100)

Next, the first mask blank 100 and its constituting members will be described in detail. Further, in the following description, reference numbers mentioned in FIG. 2 are used for clearly explaining respective constituting members.

### (Transparent Substrate 110)

The material of the transparent substrate 110 is not particularly restricted. Here, the “transparent” means the transparency of at least 85% to light having a wavelength of 193 nm. The transparent substrate 110 may, for example, be made of quartz glass. For example, the transparent substrate 110 may be made of quartz glass doped with fluorine.

The thickness of the transparent substrate 110 is not particularly limited thereto, however, may, for example, be within a range of from 6.3 mm to 6.4 mm.

### (Light-Shielding Film 120)

The light-shielding film 120 may have any construction, so far as the light-shielding film 120 has the above described features (particularly first feature).

In the light-shielding film 120, the reflectivity R₁ measured by using the first sample may be at least 55%, and the reflectivity R₁ may, for example, be at least 60% or 65%.

The light-shielding film 120 may, for example, contain at least one metal selected from aluminum (Al), silicon (Si), molybdenum (Mo) and tungsten (W). The light-shielding film 120 may, for example, be composed of MoSi containing Al.

Further, the light-shielding film 120 may, for example, contain at least one member selected from nitrogen (N), oxygen (O), carbon (C) and hydrogen (H).

The thickness of the light-shielding film 120 is not particularly limited thereto, however, may, for example, be within a range of from 36 nm to 67 nm.

### (Antireflection Film 150)

The antireflection film 150 may have any construction, so far as the antireflection film 150 has the above described features (particularly second feature).

Further, the ratio R_{A}/R_{S} is at most 0.07, and may be at most 0.05.

The antireflection film 150 may have a thickness of from 48 nm to 62 nm. For example, the antireflection film 150 may have a thickness within a range of from 50 nm to 62 nm or within a range of from 52 nm to 60 nm.

The antireflection film 150 has a first layer 152 and a second layer 154.

Among them, for example, the first layer 152 has a refractive index n₁ of from 1.6 to 2.5 and an extinction coefficient k₁ of at most 0.1. For example, the first layer 152 may have the refractive index n₁ within a range of at least 1.7 and at most 2.3, within a range of at least 1.8 and at most 2.2 or within a range of at least 1.9 and at most 2.1. Further, the first layer 152 may, for example, have an extinction coefficient k₁ of at most 0.01, at most 0.005 or at most 0.001.

On the other hand, for example, the second layer 154 has a refractive index n₂ of from 1.0 to 1.6 and an extinction coefficient k₂ of at most 0.1. The second layer 154 may, for example, have a refractive index n₂ within a range of at least 1.2 and less than 1.6 or within a range of at least 1.4 and less than 1.6. Further, the second layer 154 may, for example, have an extinction coefficient k₂ of at most 0.01, at most 0.005, or at most 0.001.

For example, the first layer 152 may contain at least one member selected from aluminum (Al), yttrium (Y) and hafnium (Hf). For example, the first layer 152 may contain at least one member selected from aluminum oxide (AlO), aluminum oxynitride (AlON), yttrium oxide (YO), yttrium oxynitride (YON), hafnium oxide (HfO) and hafnium oxynitride (HfON).

Further, the second layer 154 may, for example, contain silicon (Si). The second layer 154 may, for example, contain at least one member selected from silicon oxide (SiO) and silicon oxynitride (SiON).

The first layer 152 may have a thickness within a range of from 9 nm to 40 nm. On the other hand, the second layer 154 may have a thickness within a range of from 20 nm to 45 nm.

### Second Embodiment

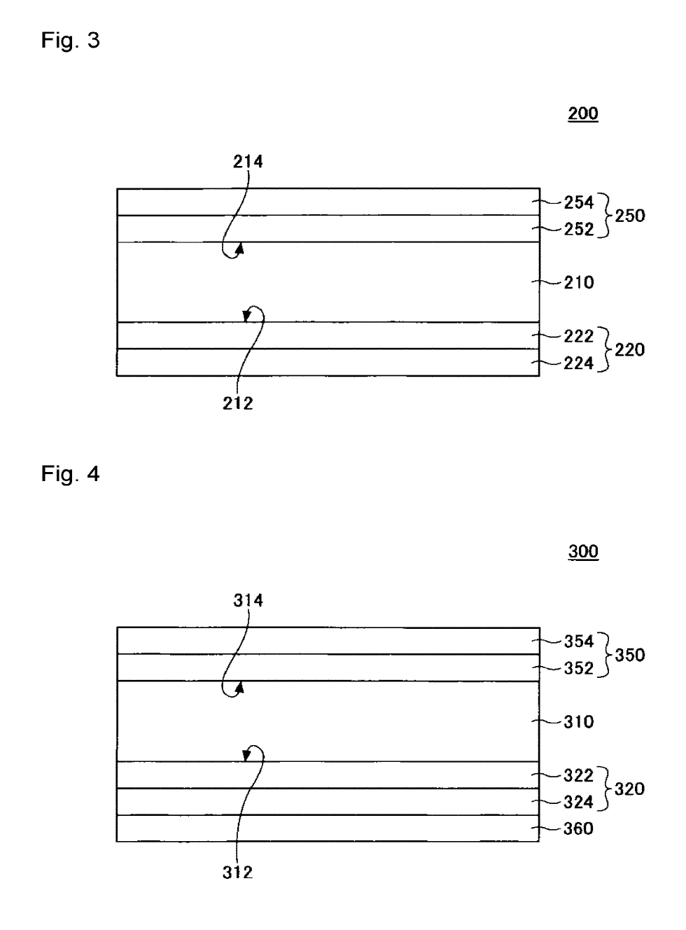

FIG. 3 shows a schematic cross-sectional view of another mask blank in another embodiment of the present invention.

As illustrated in FIG. 3, the mask blank (hereinafter, referred to also as “second mask blank”) 200 has a transparent substrate 210, a light-shielding film 220 and an antireflection film 250 (a first layer 252 and a second layer 254).

Here, the second mask blank 200 basically has a similar construction to the first mask blank 100 illustrated in FIG. 1. However, the second mask blank 200 is different from the first mask blank 100 in the point that the light-shielding film 220 is composed of at least two layers. For example, in an example illustrated in FIG. 2, the light-shielding film 220 is composed of two layers of a lower layer 222 and an upper layer 224 from the side close to the transparent substrate 210.

The second mask blank 200 also has two features similar to the first mask blank 100. That is, in a sample (first sample) obtained by removing the antireflection film 250 from the second mask blank 200, the reflectivity R₁ to be obtained by irradiating the second main surface 214 side of the transparent substrate 210 with light (for example, ArF excimer laser) having a wavelength of 193 nm at an incident angle of θ₁=5°, is at least 50%.

Further, the second mask blank 200 has a feature that in a sample (second sample) obtained by removing the light-shielding film 220 from the second mask blank 200, the ratio R_{A}/R_{S} is at most 0.1, where R_{A} is a reflectivity to be obtained by irradiating the first main surface 212 side of the transparent substrate 210 with the light (for example, ArF excimer laser) at an incident angle θ₂=5°, and R_{S} is a reflectivity similarly measured with only the transparent substrate 210.

Accordingly, in the second mask blank 200, the thermal expansion of the light-shielding film 220 and the distortion of the transparent substrate 210 can also be effectively suppressed. Further, it is possible to effectively suppress such a problem that light reflected on the light-shielding film 220 is reflected again by the second main surface 214 of the transparent substrate 210, and a processed substrate is irradiated through the first main surface 212.

Thus, when the second mask blank 200 is used as the mask for the transferring process, the deterioration of the accuracy of transferring a pattern can also be effectively suppressed.

### (Constituting Members of Second Mask Blank 200)

Next, the constituting members of the second mask blank 200 will be described in detail.

Here, regarding some constituting members of the second mask blank 200, the descriptions about the constituting members of the first mask blank 100 can be referred. Thus, only the light-shielding film 220 will be described below. Further, in the following description, reference numbers mentioned in FIG. 3 are used in order to clearly explain respective constituting members.

### (Light-Shielding Film 220)

The light-shielding film 220 has a lower layer 222 and an upper layer 224. The light-shielding film 220 has a two layers-structure, whereby the reflectivity R₁ can be further improved. Further, the light-shielding film 220 may be composed of at least three layers.

The light-shielding film 220 may have the total thickness within a range of from 36 nm to 67 nm.

### (Lower Layer 222)

The lower layer 222 of the light-shielding film 220 has a metal containing Al. For example, the lower layer 222 may be an Al layer. Further, the lower layer 222 may, for example, contain at least one member selected from nitrogen (N), oxygen (O), carbon (C) and hydrogen (H).

The thickness of the lower layer 222 is not particularly limited thereto, however, may, for example, be within a range of from 3 nm to 15 nm.

### (Upper Layer 224)

The upper layer 224 of the light-shielding film 220 may contain at least one metal selected from silicon (Si), molybdenum (Mo), tungsten (W), tantalum (Ta) and chromium (Cr). Further, the upper layer 224 may, for example, contain at least one member selected from nitrogen (N), oxygen (O), carbon (C) and hydrogen (H).

The thickness of the upper layer 224 is not particularly limited thereto, however, may, for example, be within a range of from 27 nm to 52 nm.

### Third Embodiment

FIG. 4 shows a schematic cross-sectional view of another mask blank in still another embodiment of the present invention.

As illustrated in FIG. 4, the mask blank (hereinafter, referred to as “third mask blank”) 300 basically has a similar construction to the second mask blank 200 illustrated in FIG. 2. For example, the third mask blank 300 has a transparent substrate 310, a light-shielding film 320 (a lower layer 322 and an upper layer 324) and an antireflection film 350 (a first layer 352 and a second layer 354).

The third mask blank 300 also has two features similar to the first mask blank 100 and the second mask blank 200. That is, in a sample (first sample) obtained by removing the antireflection film 350 from the third mask blank 300, the reflectivity R₁ to be obtained by irradiating the second main surface 314 side of the transparent substrate 310 with light (for example, ArF excimer laser) having a wavelength of 193 nm at an incident angle of θ₁=5°, is at least 50%.

Further, the third mask blank 300 has a feature that in a sample (second sample) obtained by removing the light-shielding film 320 from the third mask blank 300, the ratio R_{A}/R_{S} is at most 0.1, where R_{A} is a reflectivity to be obtained by irradiating the first main surface 312 side of the transparent substrate 310 with the light (for example, ArF excimer laser) at an incident angle θ₂=5°, and R_{S} is a reflectivity similarly measured with only the transparent substrate 310.

Accordingly, in the third mask blank 300, the thermal expansion of the light-shielding film 320 and the distortion of the transparent substrate 310 can also be effectively suppressed. Further, it is possible to effectively suppress such a problem that light reflected on the light-shielding film 320 is reflected again by the second main surface 314 of the transparent substrate 310, and light is irradiated on a processed substrate through the first main surface 312.

Here, the third mask blank 300 further has a second antireflection film 360 at the outside of the light-shielding film 320.

When the third mask blank 300 is used as a mask for the transferring process, the second antireflection film 360 has a role to suppress light reflected from the side of a processed substrate from entering the processed substrate again.

For example, in an ordinal transferring process, a part of light applied on a processed substrate is reflected toward a surface (first main surface) of a mask from the processed substrate. Here, the reflected light enters into the inside of the mask as it is at a part of the first main surface having no pattern of the light-shielding film (then, the reflected light comes out from an opposite surface (second main surface) of the mask). However, at a part of the first main surface having a pattern of the light-shielding film, light reflected by the side of the processed substrate is reflected again by the mask, and the reflected light may enter into the processed substrate. If such a phenomenon results, the accuracy of a pattern to be transferred on the processed substrate deteriorates.

However, the third mask blank 300 has the second antireflection film 360, whereby such a problem can be effectively prevented. Thus, when the third mask blank 300 is used as a mask for the transferring process, the deterioration of the accuracy of the pattern transferring can be further suppressed.

The construction of the second antireflection film 360 is not particularly restricted. For example, the second antireflection film 360 may be composed of an oxide or an oxynitride.

For example, the second antireflection film 360 may be composed of the material for constituting the upper layer 324 of the light-shielding film 320, such as at least one oxide or oxynitride of silicon (Si), molybdenum (Mo), tungsten (W), tantalum (Ta) and chromium (Cr).

The thickness of the second antireflection film 360 is not particularly limited thereto, however, may, for example, be within a range of from 2 nm to 15 nm.

As described above, embodiments of the mask blank of the present invention have been described with respect to the three constructions. However, it is obvious for those skilled in the art that the construction of the mask blank of the present invention is by no means restricted thereto. For example, the first mask blank 100 illustrated in FIG. 2 may have a second antireflection film 360 like the third mask blank 300 at the outside of the light-shielding film 120. Further, various other modifications are conceivable.

### (Process for Producing Mask Blank of the Present Invention)

Next, one example of a process for producing the mask blank in one embodiment of the present invention will be described. Further, here, one example of the production process will be described with reference to the second mask blank 200 illustrated in FIG. 3. Further, in the following description, reference numbers mentioned in FIG. 3 are used in order to clearly represent members.

The process for producing the second mask blank 200 has (1) a first step of forming a light-shielding film 220 of a first main surface 212 of the transparent substrate 210 and (2) a second step of forming an antireflection film 250 on a second main surface 214 of the transparent substrate 210.

Further, the first step and the second step may be carried out in reverse order.

In the first step, the lower layer 222 and the upper layer 224 are formed in this order as the light-shielding film 220 of the first main surface 212 of the transparent substrate 210. Further, in the second step, the first layer 252 and the second layer 254 are formed in this order as the antireflection film 250 of the second main surface 214 of the transparent substrate 210.

The lower layer 222 and the upper layer 224 of the light-shielding film 220 may be formed by means of a known film-forming method. Such a known film-forming method may, for example, include a sputtering method such as a magnetron sputtering method or an ion beam sputtering method, a PVD method, a CVD method, a vacuum vapor deposition method or an electroplating method.

For example, in a case where a lower layer 222 made of Al is formed by the sputtering method, the sputtering is carried out by using an Al target under a predetermined atmosphere. The atmosphere may contain at least one inert gas selected from the group consisting of helium (He), argon (Ar), neon (Ne), krypton (Kr) and xenon (Xe). Further, the atmosphere may further contain at least one selected from oxygen (O₂), nitrogen (N₂) and hydrogen (H₂).

For example, in a case where a lower layer 222 made of Al is formed by the magnetron sputtering method, the following process condition may be employed:

Sputtering gas: Ar gas;

Pressure: from 1.0×10⁻¹ Pa to 50×10⁻¹ Pa, preferably from 1.0×10⁻¹ Pa to 40×10⁻¹ Pa, more preferably from 1.0×10⁻¹ Pa to 30×10⁻¹ Pa;

Applied power: from 30 to 3,000 W, preferably from 100 to 3,000 W, more preferably from 500 to 3,000 W; and

Film-deposition rate: from 0.5 to 60 nm/min, preferably from 1.0 to 45 nm/min, more preferably from 1.5 to 30 nm/min.

For example, in a case where an upper layer 224 made of Si is formed by the sputtering method, the sputtering is carried out by using an Si target under a predetermined atmosphere. The atmosphere may contain at least one inert gas selected from the group consisting of helium (He), argon (Ar), neon (Ne), krypton (Kr) and xenon (Xe). Further, the atmosphere may further contain at least one selected from oxygen (O₂), nitrogen (N₂) and hydrogen (H₂).

For example, in a case where an upper layer 224 made of Si is formed by the magnetron sputtering method, the following process conditions may be employed.

Sputtering gas: Ar gas;

Pressure: from 1.0×10⁻¹ Pa to 50×10⁻¹ Pa, preferably from 1.0×10⁻¹ Pa to 40×10⁻¹ Pa, more preferably from 1.0×10⁻¹ Pa to 30×10⁻¹ Pa;

Applied power: 30 to 3,000 W, preferably from 100 to 3,000 W, more preferably from 500 to 3,000 W; and

Film-deposition rate: 0.5 to 60 nm/min, preferably from 1.0 to 45 nm/min, more preferably from 1.5 to 30 nm/min.

Similarly, the first layer 252 and the second layer 254 of the antireflection film 250 can be formed by using a known film forming technique. Such a film forming technique includes, for example, a sputtering method such as a magnetron sputtering method or an ion beam sputtering method, a PVD method, a CVD method, a vacuum vapor deposition method or an electroplating method.

For example, in a case where a first layer 252 made of AlO is formed by the sputtering method, the sputtering is carried out by using an Al target under a predetermined atmosphere. The atmosphere may contain at least one inert gas selected from the group consisting of helium (He), argon (Ar), neon (Ne), krypton (Kr) and xenon (Xe). Further, the atmosphere may further contain at least one selected from oxygen (O₂), nitrogen (N₂) and hydrogen (H₂).

For example, in a case where a first layer 252 made of AlO is formed by the magnetron sputtering method, the following process conditions may be employed.

Sputtering gas: mixed gas of Ar and O₂ (O₂ gas concentration: from 3 to 80 vol %, preferably from 5 to 60 vol %, more preferably from 10 to 40 vol %, Ar gas concentration: from 20 to 97 vol %, preferably from 40 to 95 vol %, more preferably from 60 to 90 vol %);

Pressure: from 1.0×10⁻¹ Pa to 50×10⁻¹ Pa, preferably from 1.0×10⁻¹ Pa to 40×10⁻¹ Pa, more preferably from 1.0×10⁻¹ Pa to 30×10⁻¹ Pa;

Applied power: 30 to 3,000 W, preferably from 100 to 3,000 W, more preferably from 500 to 3,000 W; and

Film-deposition rate: 0.5 to 60 nm/min, preferably from 1.0 to 45 nm/min, more preferably from 1.5 to 30 nm/min.

For example, in a case where a second layer 254 made of SiO is formed by the sputtering method, the sputtering is carried out by using an Si target under a predetermined atmosphere. The atmosphere may contain at least one inert gas selected from the group consisting of helium (He), argon (Ar), neon (Ne), krypton (Kr) and xenon (Xe). Further, the atmosphere may further contain at least one selected from oxygen (O₂), nitrogen (N₂) and hydrogen (H₂).

For example, in a case where a second layer 254 made of SiO is formed by the magnetron sputtering method, the following process conditions may be employed.

Sputtering gas: mixed gas of Ar and O₂ (O₂ gas concentration: from 3 to 80 vol %, preferably from 5 to 60 vol %, more preferably from 10 to 40 vol %, Ar gas concentration: from 20 to 97 vol %, preferably from 40 to 95 vol %, more preferably from 60 to 90 vol %);

Pressure: from 1.0×10⁻¹ Pa to 50×10⁻¹ Pa, preferably from 1.0×10⁻¹ Pa to 40×10⁻¹ Pa, more preferably from 1.0×10⁻¹ Pa to 30×10⁻¹ Pa;

Applied power: 30 to 3,000 W, preferably from 100 to 3,000 W, more preferably from 500 to 3,000 W; and

Film-deposition rate: 0.5 to 60 nm/min, preferably from 1.0 to 45 nm/min, more preferably from 1.5 to 30 nm/min.

By the above steps (1) and (2), the second mask blank 200 can be produced. Further, it is obvious for those skilled in the art that a mask blank having another construction such as the first mask blank 100 or the third mask blank 300 can be produced by a similar method.

For example, in a case where the third mask blank 300 is produced, after the step (1) and (2), the second antireflection film 360 can be formed on the light-shielding film 320 by oxidizing or nitriding a surface (upper surface 324) of the light-shielding film 320.

### EXAMPLES

Now, Examples of the present invention will be described.

Samples for evaluation were prepared by the following methods described in Ex. 1 to 15. Further, the obtained samples were subjected to respective evaluations.

### Ex. 1

First, a quartz glass substrate having a size of a length of 152 mm×a width of 152 mm×a thickness of 6.35 mm was prepared.

Then, a light-shielding film consisting of a monolayer was formed on the first main surface (surface of length 152 mm×width 152 mm) of the glass substrate.

The light-shielding film was formed by the magnetron sputtering method as an Al layer. An Al target was used as the target, and argon gas (Ar) was used as the sputtering gas. Further, the applied power was 700 W. The thickness of the Al layer was 55 nm.

The obtained sample is referred to as “sample 1”.

### Ex. 2 to 6

A light-shielding film consisting of a monolayer was formed on a quartz glass substrate by the magnetron sputtering method in the same manner as in Ex. 1. In Ex. 2, a light-shielding film having a thickness of 48 nm and made of Si was formed. In Ex. 3, a light-shielding film having a thickness of 49 nm and made of Mo was formed. In Ex. 4, a light-shielding film having a thickness of 36 nm and made of W was formed. In Ex. 5, a light-shielding film having a thickness of 49 nm and made of Ta was formed. In Ex. 6, a light-shielding film having a thickness 69 nm and made of Cr was formed.

These samples are referred to as “sample 2” to “sample 6” respectively.

### (Evaluation)

By using respective samples 1 to 6, the reflectivity and the transmittance to light having a wavelength of 193 nm were evaluated.

A spectrophotometer (UV-4100: manufactured by Hitachi High-Technologies Corporation) was used for the measurements. Further, the reflectivity is a value obtained by applying light at an incident angle θ₁=5° from a side of the sample where the light-shielding film was not formed. On the other hand, the transmittance is a value obtained by applying light at an incident angle=0° from a side of the sample where the light-shielding film was not formed.

Results are shown in Table 1 together.

TABLE 1

| | Light-shielding film | | | |
|---|---|---|---|---|
| | | Thickness | Reflectivity | Transmittance |
| Sample | Material | (nm) | (%) | (%) |
| 1 | Al | 55 | 90.7 | 0.10 |
| 2 | Si | 48 | 56.8 | 0.09 |
| 3 | Mo | 49 | 56.3 | 0.09 |
| 4 | W | 36 | 54.1 | 0.09 |
| 5 | Ta | 49 | 40.4 | 0.09 |
| 6 | Cr | 69 | 40.2 | 0.10 |

It is evident from Table 1 that the transmittance was at most 0.1% in all of the samples 1 to 6. Accordingly, as is evident form the above, the layers formed in the sample 1 to sample 6 have an excellent light-shielding property.

Further, in all of the sample 1 (the light-shielding film was an Al layer), the sample 2 (the light-shielding film was an Si layer), the sample 3 (the light-shielding film was an Mo layer) and the sample 4 (the light-shielding film was a W layer), the reflectivity was at least 50%. Accordingly, in a case where a light-shielding film for a mask blank (and a mask) is formed by using such materials, it is assumed that the generation of heat due to the absorption of irradiated light can be effectively suppressed.

On the other hand, in the sample 5 (the light-shielding film was a Ta layer) and the sample 6 (the light-shielding film was a Cr layer), the reflectivity was less than 50%. Accordingly, it is assumed that in a case where a light-shielding film for a mask blank (and a mask) is formed by using such a material, it is difficult to sufficiently suppress the heat generation due to the absorption of irradiated light.

### Ex. 7

A quartz glass substrate having a size of length 152 mm×width 152 mm×thickness 6.35 mm was prepared.

Then, a light-shielding film constituting of two layers was formed on a first main surface (surface of length 152 mm×width 152 mm) of the glass substrate. The light-shielding film had an Al layer as the lower layer and an Si layer as the upper layer.

Respective layers were formed by the magnetron sputtering method. An Al target was used as a target for forming the lower layer, and an Si target was used as a target for forming the upper layer.

Argon gas (Ar) was used as a sputtering gas for forming both layers. Further, applied power was 700 W. The Al layer had a thickness of 3 nm, and the Si layer had a thickness of 45 nm.

An obtained sample is referred to as “sample 7”.

### Ex. 8 to Ex. 15

A light-shielding film consisting of two layers was formed on a quartz glass substrate by the magnetron sputtering method in the same manner as in Ex. 7.

In Ex. 8, as the light-shielding film, an Al layer (lower layer) having a thickness of 15 nm was formed, and then an Si layer (upper layer) having a thickness of 35 nm was formed. In Ex. 9, as the light-shielding film, an Al layer (lower layer) having a thickness of 3 nm was formed, and then a Mo layer (upper layer) having a thickness of 46 nm was formed. In Ex. 10, as the light-shielding film, an Al layer (lower layer) having a thickness of 15 nm was formed, and then an Mo layer (upper layer) having a thickness of 36 nm was formed. In Ex. 11, as the light-shielding film, an Al layer (lower layer) having a thickness of 3 nm was formed, and then a W layer (upper layer) having a thickness of 34 nm was formed. In Ex. 12, as the light-shielding film, an Al layer (lower layer) having a thickness of 15 nm was formed, and then a W layer (upper layer) having a thickness of 27 nm was formed. In Ex. 13, as the light-shielding film, an Al layer (lower layer) having a thickness of 3 nm was formed, and then a Ta layer (upper layer) having a thickness of 47 nm was formed. In Ex. 14, as the light-shielding film, an Al layer (lower layer) having a thickness of 15 nm was formed, and then a Ta layer (upper layer) having a thickness of 37 nm was formed. In Ex. 15, as the light-shielding film, an Al layer (lower layer) having a thickness of 15 nm was formed, and then a Cr layer (upper layer) having a thickness of 52 nm was formed.

These samples are referred to as “sample 8” to “sample 15”, respectively.

### (Evaluation)

By using the respective samples 7 to 15, the reflectivity and the transmittance to light having a wavelength of 193 nm were measured by the above method.

Results are shown in the following Table 2 together.

TABLE 2

| | Light-shielding film | | Light-shielding film | | Thickness | | |
|---|---|---|---|---|---|---|---|
| | (upper layer) | | (lower layer) | | of light- | | |
| | | Thickness | | Thickness | shielding | Reflectivity | Transmittance |
| Sample | Material | (nm) | Material | (nm) | film | (%) | (%) |
| 7 | Al | 3 | Si | 45 | 48 | 66.7 | 0.10 |
| 8 | Al | 15 | Si | 35 | 50 | 86.0 | 0.10 |
| 9 | Al | 3 | Mo | 46 | 49 | 66.3 | 0.10 |
| 10 | Al | 15 | Mo | 36 | 51 | 85.9 | 0.10 |
| 11 | Al | 3 | W | 34 | 37 | 63.9 | 0.10 |
| 12 | Al | 15 | W | 27 | 42 | 85.4 | 0.09 |
| 13 | Al | 3 | Ta | 47 | 50 | 53.0 | 0.09 |
| 14 | Al | 15 | Ta | 37 | 52 | 82.5 | 0.09 |
| 15 | Al | 15 | Cr | 52 | 67 | 82.6 | 0.09 |

It is evident from Table 2 that in all of the sample 7 to the sample 15, the reflectivity of at least 50% could be achieved, while maintaining the transmittance to at most 0.1%. Particularly, it is evident by comparing the sample 5, the sample 13 and the sample 14 that although it is difficult to obtain a sufficient reflectivity with the monolayer of the Ta layer, the reflectivity of at least 50% can be achieved by employing the two layers structure consisting of a Ta layer and the Al layer. Similarly, it is evident by comparing the sample 6 and the sample 15 that although it is difficult to obtain a sufficient reflectivity with the monolayer of the Cr layer, the reflectivity of at least 50% can be achieved by employing the two layers structure consisting of the Cr layer and the Al layer.

Accordingly, it is assumed that in a case where a light-shielding film having two layers structure is used for a mask blank (and a mask), the heat generation due to the absorption of the irradiated light can be effectively suppressed.

### Ex. 16

By the following method of simulation, the antireflection effect of a sample having an antireflection film was evaluated.

A sample to be evaluated (referred to as “sample 16”) was prepared so as to have a construction having a first layer and a second layer in this order on one surface (second main surface) of a quartz glass substrate. As the first layer, an AlO layer was formed, and as the second layer, an SiO layer was formed.

### (Evaluation of Optical Constant)

Prior to the simulation, the optical constant of the AlO layer formed on the quartz glass substrate and the optical constant of the SiO layer formed on the quartz glass substrate were evaluated.

A spectral ellipsometer (model No.: M-2000DI, manufactured by J. A. Woollam Japan) was used for the measurement.

As a result of the measurement, the refractive index of the AlO layer was 1.941, and the extinction coefficient k was 0.000. Further, the refractive index of the SiO layer was 1.557, and the extinction coefficient k was 0.000.

### (Evaluation of Simulation)

By using the above measured optical constant, the following evaluation was carried out.

In the sample 16, R_{A} is a reflectivity to be obtained irradiating the first main surface (surface opposite to the second main surface) side with light having a wavelength of 193 nm at an incident angle θ₂=5°. Further, in the case of a quartz glass substrate having no first layer neither second layer, R_{S} is a reflectivity to be similarly obtained (R_{S}=4.9%). The change of the ratio R_{A}/R_{S} to be obtained independently changing the thickness of the first layer (an Al layer) and the thickness of the second layer (SiO layer) each other is evaluated by the simulated calculation.

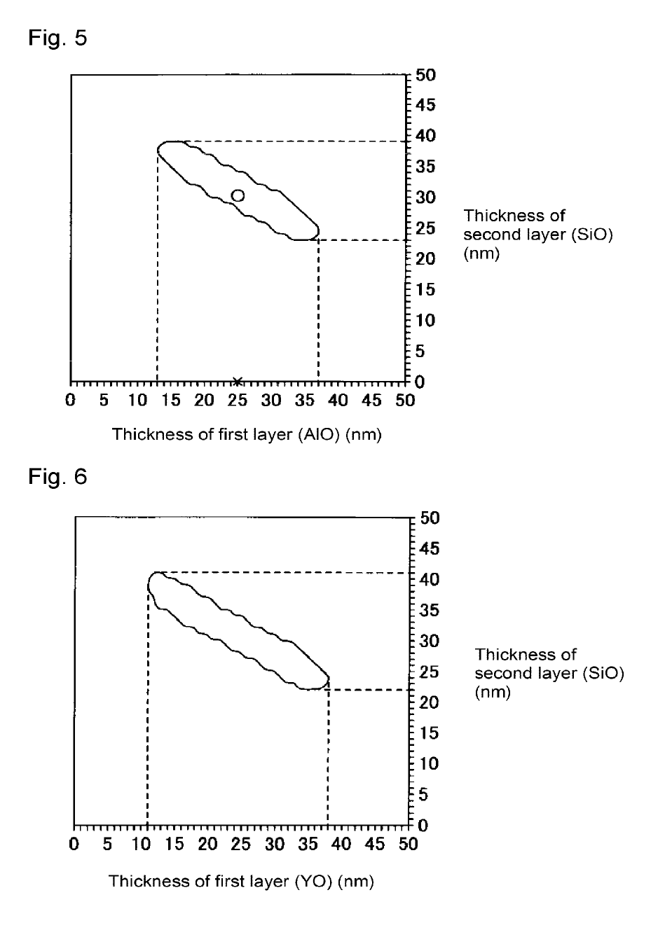

FIG. 5 shows a result of mapping regions obtained by the simulated calculation where the R_{A}/R_{S} was at most 0.1. In FIG. 5, the horizontal axis is the thickness of the first layer (AlO layer), and the vertical axis is the thickness of the second layer (SiO layer). Further, the inside area of a loop line corresponds to the ratio R_{A}/R_{S}≦0.1 (that is, the loop line represents the ratio R_{A}/R_{S}=0.1).

It is evident from the Figure that in a case where the thickness of the first layer falls within a range of from 13 nm to 37 nm and the thickness of the second layer falls within a range of from 23 nm to 39 nm, the ratio R_{A}/R_{S} is at most 0.1, whereby an excellent low reflection effect can be obtained.

In order to confirm the above, the ratio R_{A}/R_{S} was calculated by using an actually prepared sample (sample A and sample B).

The sample A was prepared by forming an AlO layer having a thickness of 25 nm on a quartz glass substrate by the magnetron sputtering method. Further, the sample B was prepared by forming an AlO layer having a thickness of 25 nm on a quartz glass substrate and then forming an SiO layer having a thickness of 31 nm by the magnetron sputtering method.

By using the sample A and the sample B, the reflectivity of the surface side where the layer was not formed on the quartz glass substrate was measured (incident angle θ₂=5′). Further, from a result of the measurement, the ratio R_{A}/R_{S} was calculated. As a result, the sample A had R_{A}=16.9% and the ratio R_{A}/R_{S}=3.4. On the other hand, the sample B had R_{A}=0.01% and the ratio R_{A}/R_{S}=0.002. It is evident from these result that in the sample B, an excellent low reflection effect could be obtained.

In FIG. 5, the results of both samples A and B are plotted. As represented by the symbol x, in the sample A, the ratio R_{A}/R_{S} is not included in the area of the ratio R_{A}/R_{S}≦0.1. On the other hand, in the sample B, as represented by the symbol ◯, the ratio R_{A}/R_{S} is included in the area of the ratio R_{A}/R_{S}≦0.1.

Thus, the actually measured results agree with the simulated results.

Accordingly, it is confirmed that when the antireflection film is consisting of an AlO (first layer) and an SiO (second layer), by appropriately selecting their film thickness, a sufficient antireflection effect can be obtained.

### Ex. 17

The antireflection effect of a sample having an antireflection film was evaluated by the simulation in the same manner as in Ex. 16.

A sample to be evaluated (referred to as “sample 17”) was produced so as to have a first layer and a second layer in this order on one surface (second main surface) of a quartz glass substrate. As the first layer, a YO layer was formed, and as the second layer, an SiO layer was formed. Further, as a result of measuring an optical constant in the same manner as in Ex. 16, the refractive index of the YO layer was 1.990, and the extinction coefficient k was 0.000.

FIG. 6 shows a result of mapping an area where the ratio R_{A}/R_{S} is at most 0.1. In FIG. 6, the horizontal axis is the film thickness of the first layer (YO layer), and the vertical axis is the thickness of the second layer (SiO layer). Further, in the Figure, the inside area of a loop line corresponds to the ratio R_{A}/R_{S}≦0.1 (that is, the loop line represents the ratio R_{A}/R_{S}=0.1).

It is evident from the Figure that in a case where the thickness of the first layer falls within a range of from 11 nm to 38 nm and the thickness of the second layer falls within a range of from 22 nm to 41 nm, the ratio R_{A}/R_{S} is at most 0.1.

Thus, it is confirmed that when the antireflection film is consisting of the YO (first layer) and SiO (second layer), by appropriately selecting their film thickness, a sufficient antireflection effect can be obtained.

### Ex. 18

The antireflection effect of a sample having an antireflection film was evaluated by the simulation in the same manner as in Ex. 16.

A sample to be evaluated (referred to as “sample 18”) was produced so as to have a first layer and a second layer in this order on one surface (second main surface) of a quartz glass substrate. As the first layer, an HfO layer was formed, and as the second layer, an SiO layer was formed. Further, as a result of measuring an optical constant in the same manner as in Ex. 16, the refractive index of the HfO layer was 2.056, and the extinction coefficient k was 0.000.

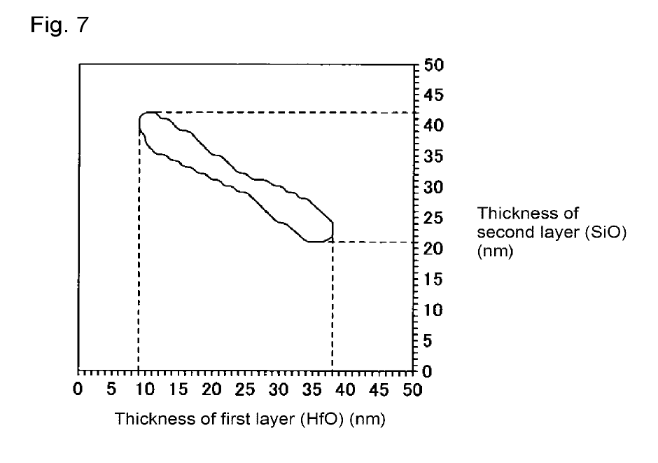

FIG. 7 shows a result of mapping an area where the ratio R_{A}/R_{S} is at most 0.1. In FIG. 7, the horizontal axis is the film thickness of the first layer (HfO layer), and the vertical axis is the thickness of the second layer (SiO layer). Further, in the Figure, the inside area of a loop line corresponds to the ratio R_{A}/R_{S}≦0.1 (that is, the loop line represents the ratio R_{A}/R_{S}=0.1).

It is evident from the Figure that in a case where the thickness of the first layer falls within a range of from 9 nm to 38 nm and the thickness of the second layer falls within a range of from 21 nm to 42 nm, the ratio R_{A}/R_{S} is at most 0.1.

Thus, it is evident that when the antireflection film is consisting of the HfO (first layer) and SiO (second layer), by appropriately selecting their film thickness, a sufficient antireflection effect can be obtained.

It is confirmed in the above evaluation results that by appropriately selecting the materials and the thickness of the light-shielding film and the antireflection film, the reflectivity of the light-shielding film defined as described above is made to be at least 50%, and the ratio R_{A}/R_{S} defined as described above in the antireflection film is made to be at most 0.1. By using a mask blank having such a construction, the deterioration of the accuracy of the pattern transferring can be effectively suppressed.

The entire disclosure of Japanese Patent Application No. 2015-179033 filed on Sep. 11, 2015 including specification, claims, drawings and summary is incorporated herein by reference in its entirety.

### REFERENCE SYMBOLS

1: Conventional mask
10: Glass substrate
12: First main surface
14: Second main surface
20: Light-shielding film
90: Substrate to be processed
100: First mask blank
110: Transparent substrate
112: First main surface
114: Second main surface
120: Light-shielding film
150: Antireflection film
152: First layer
154: Second layer
200: Second mask blank
210: Transparent substrate
212: First main surface
214: Second main surface
220: Light-shielding film
222: Lower layer
224: Upper layer
250: Antireflection film
252: First layer
254: Second layer
300: Third mask blank
310: Transparent substrate
312: First main surface
314: Second main surface
320: Light-shielding film
322: Lower layer
324: Upper layer
350: Antireflection film
352: First layer
354: Second layer
360: Second antireflection film

What is claimed is:

1. A mask blank having a transparent substrate, wherein the transparent substrate has a first main surface and a second main surface which are opposed each other, the first main surface is provided with a light-shielding film, the second main surface is provided with an antireflection film, the antireflection film has a first layer and a second layer from the side which is close to the transparent substrate,
the reflectivity R₁ to be obtained by removing the antireflection film from the mask blank and irradiating the second main surface side of the transparent substrate with light having a wavelength of 193 nm at an incident angle of θ₁=5°, is at least 50%,
the ratio R_{A}/R_{S} is at most 0.1, where R_{A} is a reflectivity to be obtained by removing the light-shielding film from the mask blank and irradiating the first main surface side of the transparent substrate with the light at incident angle of θ₂=5°, and R_{S} is a reflectivity similarly measured with only the transparent substrate,
the antireflection film has a film thickness within a range of from 48 nm to 62 nm, and
the first layer of the antireflection film comprises an oxide or oxynitride containing at least one metal selected from aluminum (Al), yttrium (Y) and hafnium (Hf).

2. The mask blank according to claim 1, wherein the antireflection film consists of two layers of the first layer and the second layer.

3. The mask blank according to claim 2, wherein the first layer of the antireflection film has a refractive index of at least 1.6 and at most 2.5, and an extinction coefficient of at most 0.1.

4. The mask blank according to claim 2, wherein the second layer of the antireflection film has a refractive index of at least 1.0 and less than 1.6, and an extinction coefficient of at most 0.1.

5. The mask blank according to claim 2, wherein the second layer of the antireflection film contains an oxide or oxynitride of silicon (Si).

6. The mask blank according to claim 1, wherein the light-shielding film has a film thickness within a range of from 36 to 67 nm.

7. The mask blank according to claim 1, wherein the light-shielding film contains at least one metal selected from aluminum (Al), silicon (Si), molybdenum (Mo), tungsten (W), tantalum (Ta) and chromium (Cr).

8. The mask blank according to claim 1, wherein the light-shielding film has at least two layers of a lower layer and an upper layer from the side which is close to the transparent substrate,
the lower layer contains aluminum (Al), and the upper layer contains at least one metal selected from the group consisting of silicon (Si), molybdenum (Mo), tungsten (W), tantalum (Ta) and chromium (Cr).

9. The mask blank according to claim 1, wherein the transparent substrate is made of quartz glass or fluorine-doped quartz glass.
